(19) United States
(12) Patent Application Publication
(10) Pub. No.: US 2022/0376588 A1
(43) Pub. Date: Nov. 24, 2022

(54) DRIVE DEVICE

(71) Applicant: NIDEC CORPORATION, Kyoto (JP)

(72) Inventors: Keigo NAKAMURA, Kyoto (JP); Hibiki TAKADA, Kyoto (JP); Kazunori TATEGATA, Kyoto (JP)

(21) Appl. No.: 17/770,988

(22) PCT Filed: Sep. 17, 2020
(86) PCT No.: PCT/JP2020/035323

§ 371 Date: Apr. 21, 2022

(30) Foreign Application Priority Data
Oct. 21, 2019 (JP) 2019-192064

(51) Int. Cl. H02K 11/33; H02K 5/20; H02K 7/116; H02K 9/19; H02P 27/06

(52) U.S. Cl. CPC H02K 11/33; H02K 5/20; H02K 7/116; H02K 9/19; H02P 27/06

(57) ABSTRACT

A drive device includes a motor having a motor shaft that rotates, a motor housing unit that houses the motor, a gear unit that transmits rotation of the motor shaft to an intermediate shaft, and an inverter housing unit that houses the inverter, wherein the inverter housing unit is disposed above the intermediate shaft, a lower wall portion of the inverter housing unit faces outside air, and the inverter housing unit has a vent that allows an inside of the inverter housing unit and an outside below the inverter housing unit to communication with each other.

### CROSS-REFERENCE TO RELATED APPLICATIONS

This is the U.S. national stage of application No. PCT/JP2020/035323, filed on Sep. 17, 2020, and priority under 35 U.S.C. § 119 (a) and 35 U.S.C. § 365(b) is claimed from Japanese Patent Application No. 2019-192064, filed on Oct. 21, 2019.

### FIELD OF THE INVENTION

The present invention relates to a drive device.

### BACKGROUND

In a drive device including a motor and an inverter that controls an operation of the motor, when the motor or the inverter generates heat, air inside a case that houses the motor or the inverter expands, and pressure in an internal space may increase. For this reason, a configuration is known in which a valve that opens when a pressure in an internal space increases is provided in a case that houses a motor or an inverter and the internal space communicates with outside air.

In the conventional drive device, the valve is provided only in the case that houses the motor with the internal space of the case that houses the motor and the internal space of the housing that houses the inverter communicating with each other. However, depending on the configuration of the drive device, the internal space of the case that houses the motor and the internal space of the housing that houses the inverter may not be desired to communicate with each other. Therefore, there is a problem in that the internal pressure cannot be independently adjusted with respect to the housing that houses the inverter.

In addition, in a case where components inside the motor are oil-cooled in a configuration in which the internal space of the case that houses the motor and the internal space of the housing that houses the inverter communicate with each other, there is a possibility that oil for cooling the motor enters the inverter.

### SUMMARY

An exemplary drive device of the present invention includes a motor having a motor shaft that rotates about a center axis, a motor housing unit that houses the motor, a gear unit that transmits rotation of the motor shaft to an intermediate shaft, a gear housing unit that houses the gear unit, an inverter that supplies power to the motor, and an inverter housing unit that houses the inverter, wherein the gear unit is provided on an axial one side of the motor housing unit, the intermediate shaft is attached to the axial other side of the gear unit, the inverter housing unit is disposed above the intermediate shaft, a lower wall portion of the inverter housing unit faces outside air, and the inverter housing unit has a vent that allows an inside of the inverter housing unit and an outside below the inverter housing unit to communication with each other.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is a conceptual view of a drive device of an preferred embodiment;

FIG. 2 is a perspective view of the drive device;

FIG. 3 is a conceptual view of a mounting place of the drive device of the vehicle on which the drive device is mounted when viewed from the rear;

FIG. 4 is an enlarged perspective view of a lower portion of an inverter housing unit of the drive device;

FIG. 5 is an enlarged perspective view of a periphery of a lower portion of an inverter housing unit of the drive device in a state where an intermediate shaft holding member is removed;

FIG. 6 is a cross-sectional view illustrating a periphery of a lower portion of an inverter housing unit of the drive device in a state where an intermediate shaft holding member is removed; and

FIG. 7 is a cross-sectional view illustrating a periphery of a lower portion of an inverter housing unit of the drive device.

### DETAILED DESCRIPTION

A drive device according to an embodiment of the present invention will be described below with reference to the drawings. Note that the scope of the present invention is not limited to the embodiments described below, but includes any modification thereof within the scope of the technical idea of the present invention.

The following description will be made with the direction of gravity being defined based on a positional relationship in the case where a drive device 1 is mounted in a vehicle located on a horizontal road surface. In the drawings, an XYZ coordinate system is shown appropriately as a three-dimensional orthogonal coordinate system. In an XYZ coordinate system, the Z direction indicates the vertical direction (that is, a up and down direction), and the +Z direction is the upper side (opposite to the gravity direction), and the −Z direction is the lower side (gravity direction). The X direction is a direction orthogonal to the Z direction and indicates a front-rear direction of a vehicle on which the drive device 1 is mounted, and the +X direction is the front side of the vehicle, and the −X direction is the rear side of the vehicle. Note that the +X direction maybe the rear side of the vehicle, and the −X direction may be the front side of the vehicle. The Y direction is a direction orthogonal to both the X direction and the Z direction, and is a width direction (left-right direction) of the vehicle. Depending on the method of mounting the drive device 1 on the vehicle, the X direction may be the width direction (left-right direction) of the vehicle, and the Y direction may be the front-rear direction of the vehicle.

In the following description, unless otherwise specified, a direction (Y direction) parallel to a motor axis J2 of a motor 2 is simply referred to as an “axial direction”, a radial direction orthogonal to the motor axis J2 is simply referred to as a “radial direction”, and a circumferential direction around the motor axis J2 is simply referred to as a “circumferential direction”. A horizontal direction including the X direction and the Y direction is referred to as a “lateral direction”. The “parallel direction” and the “horizontal direction” described above include not only a completely parallel direction and a completely horizontal direction but also a substantially parallel direction and a substantially horizontal direction.

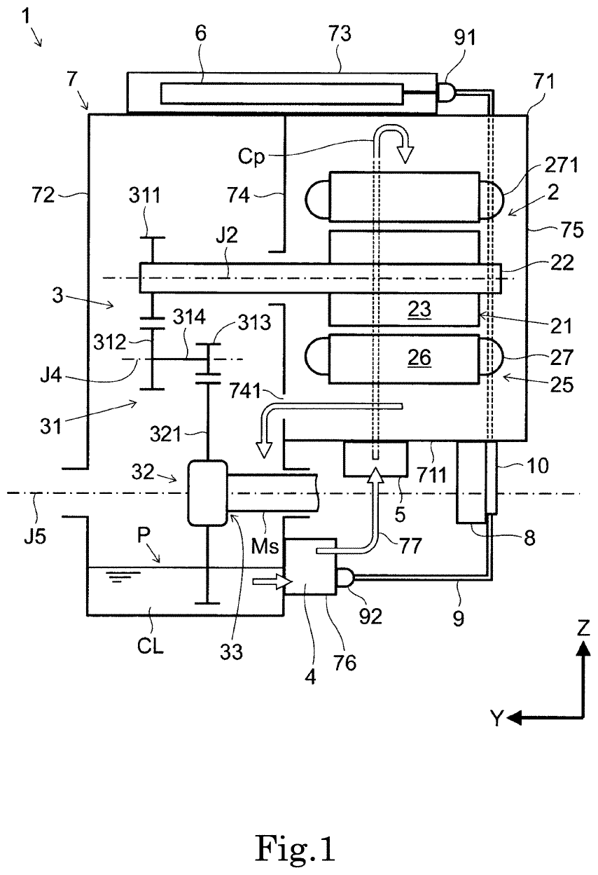

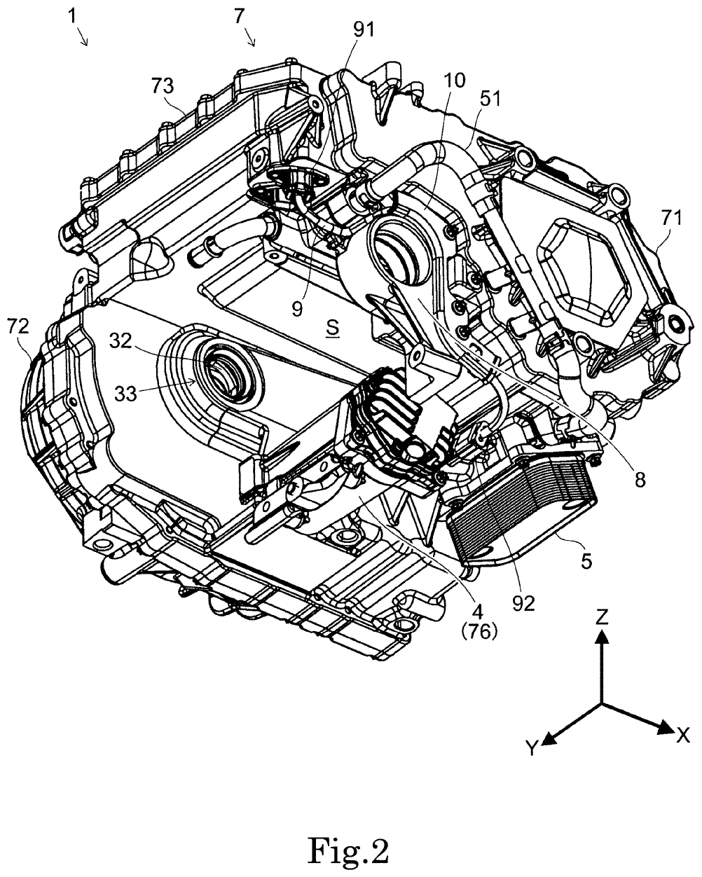

The drive device 1 according to an exemplary preferred embodiment of the present invention will be described below with reference to the drawings. FIG. 1 is a conceptual diagram of a drive device 1 according to an preferred embodiment. FIG. 2 is a perspective view of the drive device 1. Note that FIG. 1 is a conceptual diagram. The arrangement and dimensions of each unit are not necessarily the same as those of the actual drive device 1.

The drive device 1 is mounted on the vehicle such as a hybrid vehicle (HV), a plug-in hybrid vehicle (PHV), and an electric vehicle (EV) in which at least the motor is used as a power source. The drive device 1 is used as a power source of the vehicles described above.

As shown in FIGS. 1 and 2, the drive device 1 includes the motor 2, a gear unit 3, an oil pump 4, an oil cooler 5, an inverter 6, a housing 7, an intermediate shaft holding member 8, a wire harness 9, and a harness protection member 10. The housing 7 includes a motor housing unit 71 that houses the motor 2, a gear housing unit 72 that houses the gear unit 3, and an inverter housing unit 73 that houses the inverter 6.

The motor 2 is housed in the motor housing unit 71 of the housing 7. The motor 2 includes a rotor 21 and a stator 25.

The rotor 21 rotates when electric power is supplied from a battery (not shown) to the stator 25 via the inverter 6. The rotor 21 includes a motor shaft 22, a rotor core 23, and a rotor magnet (not shown). The rotor 21 rotates about a motor axis (center axis) J2 extending in the horizontal direction. That is, the motor 2 includes the motor shaft 22 that rotates about the motor axis (center axis) J2 extending in the horizontal direction.

The motor shaft 22 extends with the motor axis J2, as the center, extending in the horizontal direction and the width direction (Y direction) of the vehicle. More specifically, the motor shaft 22 is divided into a shaft on the motor 2 side and a shaft on the gear unit 3 side, and is connected using a spline shaft. The motor shaft 22 rotates about the motor axis J2.

The motor shaft 22 extends across the inside of the motor housing unit 71 and the inside of the gear housing unit 72. An end of the motor shaft 22 at an axial one side (+Y direction side) passes through a partition wall portion 74 shared by the motor housing unit 71 and the gear housing unit 72, and protrudes into the gear housing unit 72. An end of the motor shaft 22 at an axial one side (+Y direction side) is rotatably supported by a bearing (not shown) held by the partition wall portion 74. An end of the motor shaft 22 at the axial other side (−Y direction side) is rotatably supported by a bearing (not shown) held by a closing portion 75 of the motor housing unit 71.

The rotor core 23 is formed by laminating silicon steel sheets. The rotor core 23 is a columnar body extending along the axial direction. A plurality of rotor magnets (not shown) is fixed to the rotor core 23. The plurality of rotor magnets is aligned along the circumferential direction with the magnetic poles disposed alternately.

The stator 25 is located radially outside of the rotor 21 and surrounds the rotor 21 from the radially outside. That is, the motor 2 is an inner rotor type motor in which the rotor 21 is rotatably disposed inside the stator 25. The stator 25 is held by the motor housing unit 71. The stator 25 includes a stator core 26, a coil 27, and an insulator (not shown). The insulator is interposed between the stator core 26 and the coil 27. The stator core 26 has a plurality of magnetic pole teeth (not shown) radially inward from the inner peripheral face of the annular yoke.

A coil wire (not shown) is wound between the magnetic pole teeth. The coil wire wound around the magnetic pole teeth constitutes the coil 27. The coil wire is connected to the inverter 6 via a bus bar (not shown). The coil 27 includes a coil end 271 protruding from the axial end face of the stator core 26. The coil end 271 protrudes axially outward of the end of the rotor core 23 of the rotor 21.

The gear unit 3 is provided on an axial one side (left side in FIG. 1, +Y direction side) of the motor housing unit 71. The gear unit 3 is housed in the gear housing unit 72 of the housing 7. The gear unit 3 is connected to the motor shaft 22 on an axial one side (left side in FIG. 1, +Y direction side) of the motor shaft 22.

The gear unit 3 includes a deceleration device 31, a differential device 32, and an intermediate shaft connection portion 33. The gear unit 3 is attached to an intermediate shaft Ms at the axial other side (right side in FIG. 1, −Y direction side). The gear unit 3 transmits the rotation of the motor shaft 22 to the intermediate shaft Ms.

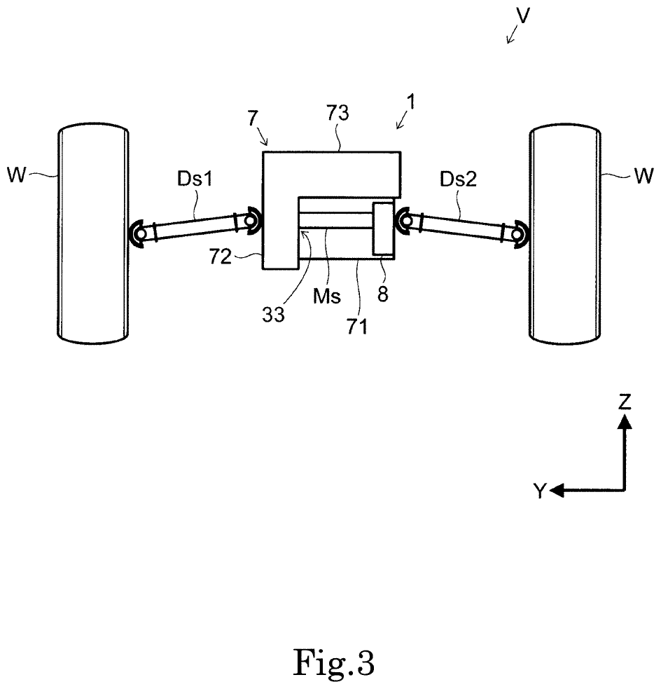

FIG. 3 is a conceptual view of a mounting place of the drive device 1 of a vehicle V on which the drive device 1 is mounted when viewed from the rear. For example, the drive shaft of the vehicle V is divided into a first drive shaft Ds1, the intermediate shaft Ms, and a second drive shaft Ds2. Rotation of the motor shaft 22 is directly transmitted from the gear unit 3 to the first drive shaft Ds1. Rotation of the motor shaft 22 is transmitted from the gear unit 3 to the second drive shaft Ds2 via the intermediate shaft Ms.

The deceleration device 31 is connected to the motor shaft 22. That is, the gear unit 3 is connected to the motor shaft 22 at an axial one side (left side in FIG. 1, +Y direction side) of the motor axis J2. The deceleration device 31 has a function of reducing a rotation speed of the motor 2 to increase torque output from the motor 2 according to a reduction gear ratio. The deceleration device 31 transmits the torque output from the motor 2 to the differential device 32.

The deceleration device 31 includes a first gear (intermediate drive gear) 311, a second gear (intermediate gear) 312, a third gear (final drive gear) 313, and a gear shaft 314. The torque output from the motor 2 is transmitted to a ring gear 321 of the differential device 32 via the motor shaft 22, the first gear 311, the second gear 312, the gear shaft 314, and the third gear 313. The gear ratio of each gear, the number of gears, and the like can be variously changed according to the required reduction gear ratio. The deceleration device 31 is a parallel axis gear type deceleration device in which the axis centers of the gears are disposed in parallel.

The first gear 311 is attached to the outer peripheral face of the motor shaft 22. The first gear 311 together with the motor shaft 22 rotate about the motor axis J2.

The gear shaft 314 extends along a gear axis J4 parallel to the motor axis J2. Both ends of the gear shaft 314 are rotatably supported by bearings (not shown) held by the gear housing unit 72. The gear shaft 314 rotates about the gear axis J4.

The second gear 312 and the third gear 313 are attached to the outer peripheral face of the gear shaft 314. The second gear 312 and the third gear 313 are connected with each other via a gear shaft 314. The third gear 313 is located closer to the partition wall portion 74 than the second gear 312. The second gear 312 and the third gear 313 rotate about the gear axis J4. The second gear 312 meshes with the first gear 311. The third gear 313 meshes with the ring gear 321 of the differential device 32.

The torque of the motor shaft 22 is transmitted from the first gear 311 to the second gear 312. The torque transmitted to the second gear 312 is transmitted to the third gear 313 via the gear shaft 314. The torque transmitted to the third gear 313 is transmitted to the ring gear 321 of the differential device 32. In this manner, the deceleration device 31 transmits, to the differential device 32, the torque output from the motor 2.

The first drive shaft Ds1 and the intermediate shaft Ms are attached to the differential device 32. The first drive shaft Ds1 and the intermediate shaft Ms are attached to the left side and the right side of the differential device 32, respectively. The differential device 32 transmits the output torque of the motor 2 to the first drive shaft Ds1 and the intermediate shaft Ms. The differential device 32 has a function of transmitting the same torque to the first drive shaft Ds1 and the intermediate shaft Ms while absorbing the difference in speed between the left and right wheels W, for example, when the vehicle V (see FIG. 3) turns.

The differential device 32 has the ring gear 321. The ring gear 321 rotates about a differential axis J5 parallel to the motor axis J2. The torque output from the motor 2 is transmitted to the ring gear 321 through the deceleration device 31.

The intermediate shaft connection portion 33 is provided in the differential device 32. The intermediate shaft connection portion 33 faces the −Y direction side (right side in FIG. 1) of the differential device 32. That is, the intermediate shaft connection portion 33 faces the axial other side opposite to the axial one side (left side in FIG. 1, +Y direction side) to which the gear unit 3 is connected in the axial direction of the motor shaft 22.

The intermediate shaft Ms extending toward the axial other side (right side in FIG. 1, −Y direction side) of the motor shaft 22 is attached to the intermediate shaft connection portion 33. The motor 2 and the intermediate shaft Ms are disposed so as to be shifted from each other in the lateral direction (X direction). That is, the intermediate shaft Ms is disposed away from the motor 2 in the lateral direction (−X direction, see FIG. 2) of the motor 2. In the present preferred embodiment, the motor axis J2 and the differential axis J5 are parallel, that is, the motor shaft 22 and the intermediate shaft Ms are parallel.

The oil pump 4 circulates the oil CL inside the motor housing unit 71. The oil pump 4 is an electric pump that includes a pump motor (not shown) and is driven by electricity. The housing 7 further includes a pump housing unit 76 that houses the oil pump 4. The oil pump 4 is housed in the pump housing unit 76.

The drive device 1 includes an oil circulation path CP for circulating the oil CL inside the motor housing unit 71. The oil circulation path CP includes the oil pump 4, an oil pipe through which the oil CL constantly circulates in one direction, a path (for example, an oil reservoir) that temporarily accumulates the oil CL, a path through which the oil CL drips down, and a path through which the oil CL goes down along a wall. For example, the oil circulation path CP is provided in a lower region of the inside of the gear housing unit 72 and includes an oil sump P in which the oil CL is stored. For example, the oil circulation path CP includes an oil pipe 77 that connects the pump housing unit 76 and the motor housing unit 71.

The oil pipe 77 supplies the oil CL discharged from the oil pump 4 to an oil reservoir (not shown) provided in an upper portion of the inside of the motor housing unit 71. The oil CL supplied to the oil reservoir is dropped to the coil end 271 of the motor 2. The coil 27 is cooled by the oil CL dropped from the oil reservoir to the coil end 271. That is, the motor 2 is cooled by the oil CL.

The oil CL that has cooled the motor 2 flows to the lower portion of the inside of the motor housing unit 71. The partition wall portion 74 has a partition wall opening 741. The oil CL flowing to the lower portion of the inside of the motor housing unit 71 flows into the gear housing unit 72 and further flows into the oil sump P at the lower portion of the gear housing unit 72.

The oil cooler 5 is connected to the oil pipe 77 midway along the oil circulation path CP of the oil pipe 77. A refrigerant pipe 51 is connected to the oil cooler 5. The refrigerant flows into the oil cooler 5 through the refrigerant pipe 51. The oil cooler 5 exchanges heat between the refrigerant and the oil CL to cool the oil CL flowing through the oil pipe 77.

One end portion of the refrigerant pipe 51 is connected to the oil cooler 5, and the other end portion of the refrigerant pipe 51 is connected to the inverter housing unit 73. In the present preferred embodiment, the refrigerant that has cooled the inverter 6 is guided to the oil cooler 5 via the refrigerant pipe 51 to cool the oil CL, but the present invention is not limited thereto. The oil CL may be cooled by a refrigerant different from the refrigerant for cooling the inverter 6. The refrigerant for cooling the inverter 6 is cooled by a radiator (not shown).

The inverter 6 is housed and fixed inside the inverter housing unit 73. The inverter 6 is electrically connected to the motor 2. The inverter 6 supplies power to the motor 2. Furthermore, the inverter 6 controls the operation of the motor 2 by controlling the current supplied to the motor 2.

The inverter 6 further supplies power to the oil pump 4. One end of the wire harness 9 is electrically connected to the inverter 6, and the other end is electrically connected to the oil pump 4. The wire harness 9 includes a power line and a signal line for driving the oil pump 4.

The wire harness 9 has connectors 91 and 92 at both ends. The connector 91 is connected to a lower wall portion 731, of the inverter housing unit 73, described later, and is electrically connected to the inverter 6 inside the inverter housing unit 73. The connector 92 is connected to the pump housing unit 76, and is electrically connected to the oil pump 4 inside the pump housing unit 76.

The harness protection member 10 is disposed in an intermediate region between the connectors 91 and 92 of the wire harness 9. The harness protection member 10 includes a harness housing portion (not shown) that covers and surrounds part of the periphery of the wire harness 9. That is, the harness protection member 10 covers at least part of the periphery of the wire harness 9.

The housing 7 includes the motor housing unit 71, the gear housing unit 72, and the inverter housing unit 73. The motor housing unit 71 houses the motor 2. The gear housing unit 72 houses the gear unit 3. The inverter housing unit 73 houses the inverter 6. The internal space of the housing 7 is partitioned by the motor housing unit 71, the gear housing unit 72, and the inverter housing unit 73 into a space that houses the motor 2, a space that houses the gear unit 3, and a space that houses the inverter 6. The housing 7 further includes the partition wall portion 74, the closing portion 75, the pump housing unit 76, and the oil pipe 77.

The motor housing unit 71 has a peripheral wall portion 711 on the outer periphery of the internal space that houses the motor 2. The peripheral wall portion 711 has a tubular shape extending along the axial direction (Y direction) of the motor axis J2. The end of the peripheral wall portion 711 at an axial one side (+Y direction side) is closed by the partition wall portion 74. The partition wall portion 74 is located at a boundary between the motor housing unit 71 and the gear housing unit 72. The end of the peripheral wall portion 711 at the axial other side (−Y direction side) is closed by the closing portion 75.

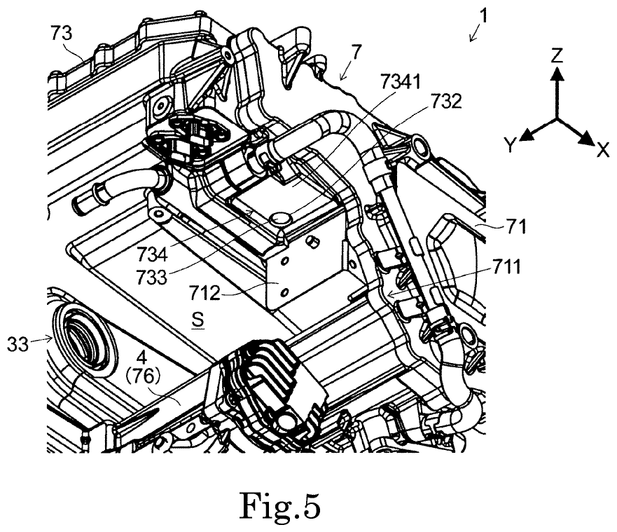

The motor housing unit 71 includes a holding member mounting portion (protection member mounting portion) 712 (see FIG. 5). The holding member mounting portion 712 is disposed at a portion, of the peripheral wall portion 711, that is an outer peripheral portion toward the intermediate shaft Ms (rear side, −X direction side) and that faces an external space S. The holding member mounting portion 712 faces the intermediate shaft Ms attached to the intermediate shaft connection portion 33.

An intermediate shaft holding member (protection member) 8 that holds the intermediate shaft Ms is attached to the holding member mounting portion 712. That is, the motor housing unit 71 includes the holding member mounting portion 712 as a protection member mounting portion to which the intermediate shaft holding member 8, which is a protection member covering a vent 732 to be described later, is attached. According to this configuration, the protection member covering the vent 732 can be supported by the motor housing unit 71.

The gear housing unit 72 is disposed at a one side of the motor housing unit 71 in the axial direction of the motor shaft 22. The gear housing unit 72 extends in the lateral direction (rear side, −X direction) of the motor 2 from a region overlapping the motor housing unit 71 when viewed in the axial direction (Y direction).

The inverter housing unit 73 is disposed across the upper portion of the motor housing unit 71 and the upper portion of the gear housing unit 72. The inverter housing unit 73 is disposed above the intermediate shaft Ms. Specifically, the inverter housing unit 73 is disposed above the intermediate shaft Ms attached to the intermediate shaft connection portion 33.

The housing 7 forms the external space S surrounded by three sides composed of the motor housing unit 71, the gear housing unit 72, and the inverter housing unit 73. The external space S is disposed on the intermediate shaft Ms side (−X direction side) of the motor housing unit 71. The external space S is disposed on the axial other side (−Y direction side) of the gear housing unit 72. The external space S is disposed below (on the −Z direction side of) the inverter housing unit 73. The intermediate shaft Ms attached to the intermediate shaft connection portion 33 is disposed in the external space S.

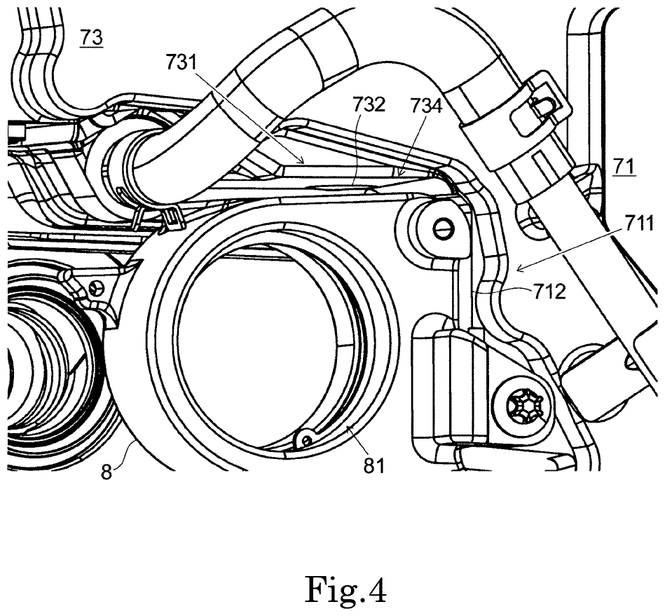

FIG. 4 is an enlarged perspective view of a lower portion of the inverter housing unit 73 of the drive device 1. In FIG. 4, the drawing of the intermediate shaft holding member 8, the wire harness 9, and the harness protection member 10 of the drive device 1 as seen in FIG. 2 is omitted.

The inverter housing unit 73 has the lower wall portion 731 below (on the −Z direction side) the internal space that houses the inverter 6. The lower wall portion 731 faces the external space S below the inverter housing unit 73. That is, the lower wall portion 731 of the inverter housing unit 73 faces the outside air.

The lower wall portion 731 of the inverter housing unit 73 has the vent 732. The vent 732 penetrates the lower wall portion 731 in the vertical direction (Z direction). The vent 732 allows the inside of the inverter housing unit 73 and the outside below the inverter housing unit 73 to communicate with each other. As a result, when the pressure inside the inverter housing unit 73 increases, air is discharged from the inside of the inverter housing unit 73 to the outside of the inverter housing unit 73.

According to the above configuration, the vent 732 for pressure adjustment can be provided for the internal space of the inverter housing unit 73. By providing the vent 732, it is possible to independently adjust the internal pressure of the inverter housing unit 73 housing the inverter 6. This is effective when the internal space of the motor housing unit 71 and the internal space of the inverter housing unit 73 are not desired to communicate with each other.

In addition, the vent 732 is provided in the lower wall portion of the inverter housing unit 73 and allows air to flow between the lower wall portion 731 and the external space S therebelow. Therefore, it is possible to prevent falling objects such as water droplets and foreign matter from entering the inverter housing unit 73 from above.

A filter member 733 (see FIG. 5) is attached to the vent 732. The filter member 733 is attachable to and detachable from the vent 732. The filter member 733 closes the vent 732 so that gas can flow, and blocks the flow of liquid and dust.

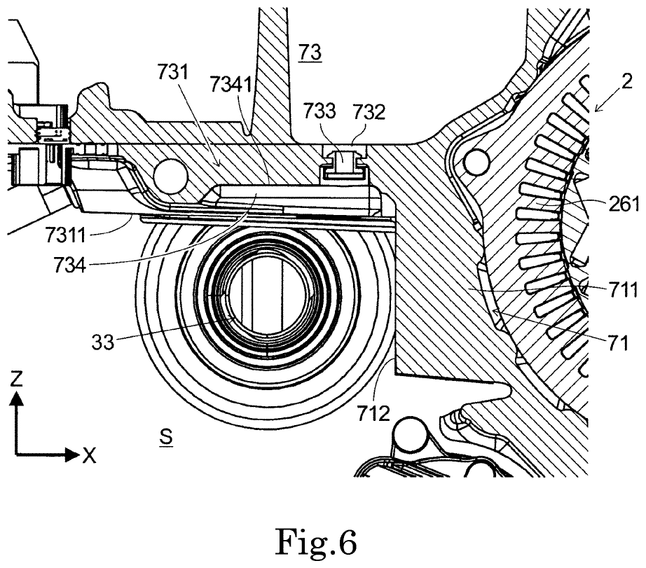

FIG. 5 is an enlarged perspective view of the periphery of the lower portion of the inverter housing unit 73 of the drive device 1 with the intermediate shaft holding member 8 removed. FIG. 6 is a cross-sectional view illustrating the periphery of the lower portion of the inverter housing unit 73 of the drive device 1 in a state where the intermediate shaft holding member 8 is removed.

The lower wall portion 731 of the inverter housing unit 73 has a recess 734. The recess 734 faces the external space S in the vertical direction (Z direction). The recess 734 is recessed upward (+Z direction) from a lower face 7311 of the lower wall portion 731. That is, the lower wall portion 731 of the inverter housing unit 73 has the recess 734 recessed upward.

The vent 732 is disposed above the recess 734. An upper portion of the recess 734 has a flat portion 7341 extending in a horizontal direction. The vent 732 is disposed at the flat portion 7341 of the recess 734. According to this configuration, it is possible to enhance an effect of making it difficult for scattering objects such as water droplets and foreign matter to go in the inverter housing unit 73 from the vent 732. In addition, the space between the vent 732 and the intermediate shaft holding member 8 (protection member) can be adjusted by the recess 734, and the air flowability of the vent 732 can be set to a suitable state.

Both the motor housing unit 71 and the inverter housing unit 73 are part of the housing 7. That is, both the motor housing unit 71 and the inverter housing unit 73 are part of a single member (housing 7). According to this configuration, the strength of the housing 7 of the entire drive device 1 can be improved. In addition, the number of parts is reduced, and the number of assembling steps can be reduced.

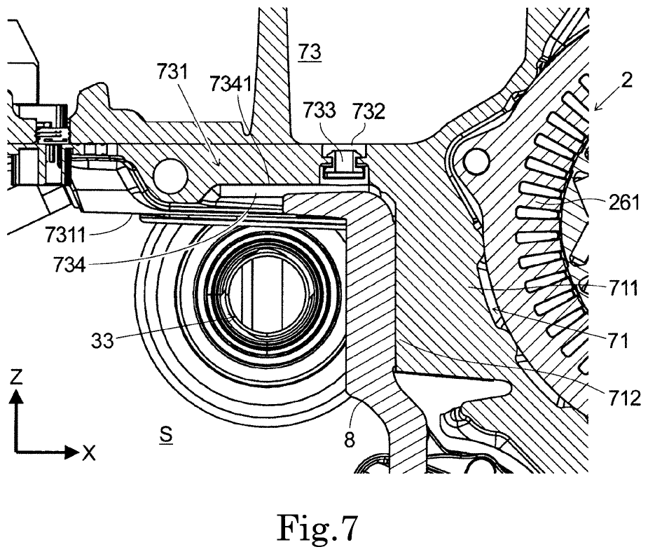

FIG. 7 is a cross-sectional view illustrating the periphery of the lower portion of the inverter housing unit 73 of the drive device 1.

The intermediate shaft holding member 8 is attached to an outer face of the peripheral wall portion 711 of the motor housing unit 71 on the intermediate shaft Ms side. The intermediate shaft holding member 8 protrudes in the lateral direction (rear side, −X direction) toward the external space S with respect to the holding member mounting portion 712 of the motor housing unit 71.

The intermediate shaft holding member 8 is disposed below the vent 732 (−Z direction) with a gap from the vent 732. The intermediate shaft holding member 8 covers the vent 732 in the vertical direction (Z direction). That is, the drive device 1 includes the intermediate shaft holding member 8 as a protection member that is disposed below the vent 732 with a gap from the vent 732 and that covers the vent 732 in the vertical direction. According to this configuration, the intermediate shaft holding member 8, which is a protection member of the vent 732, makes it possible to prevent scattering objects such as water droplets and foreign matter from entering the inverter housing unit 73 from below.

The intermediate shaft holding member 8 has a holding hole 81 (see FIG. 4). The holding hole 81 penetrates the intermediate shaft holding member 8 in the axial direction (Y direction). A bearing member (not shown) is attached to the holding hole 81. The intermediate shaft Ms attached to the intermediate shaft connection portion 33 is inserted into the holding hole 81. Thus, the intermediate shaft holding member 8 rotatably holds the intermediate shaft Ms. That is, the intermediate shaft holding member 8 which is a protection member of the vent 732 rotatably holds the intermediate shaft Ms. According to this configuration, the intermediate shaft holding member 8 for holding the intermediate shaft Ms can also be used as a protection member of the vent 732.

Although the preferred embodiments of the present invention have been described above, the scope of the present invention is not limited thereto. The present invention can be carried out with addition, omission, substitution, and various other modifications without departing from the gist of the present invention.

The drive device of the present invention can be used as a drive device for, for example, a hybrid vehicle (HV), a plug-in hybrid vehicle (PHV), and an electric vehicle (EV). Furthermore, the drive device of the present invention is not limited to a drive device for a vehicle, and can be used as a drive device for a means of transport such as a ship or an aircraft.

Features of the above-described preferred embodiments and the modifications thereof may be combined appropriately as long as no conflict arises.

While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

1. A drive device comprising:
a motor having a motor shaft that rotates about a center axis;
a motor housing unit that houses the motor;
a gear unit that transmits rotation of the motor shaft to an intermediate shaft;
a gear housing unit that houses the gear unit;
an inverter that supplies power to the motor; and
an inverter housing unit that houses the inverter,
wherein the gear unit is provided on an axial one side of the motor housing unit,
the intermediate shaft is attached to the axial other side of the gear unit,
the inverter housing unit is disposed above the intermediate shaft,
a lower wall portion of the inverter housing unit faces outside air, and
the inverter housing unit has a vent that allows an inside of the inverter housing unit and an outside below the inverter housing unit to communication with each other.

2. The drive device according to claim 1, further comprising: a protection member disposed below the vent with a gap from the vent and covering the vent in a vertical direction.

3. The drive device according to claim 2, wherein the protection member rotatably holds the intermediate shaft.

4. The drive device according to claim 3, wherein the motor housing unit includes a protection member mounting portion to which the protection member is attached.

5. The drive device according to claim 1, wherein
the lower wall portion of the inverter housing unit has a recess recessed upward, and
the vent is disposed above the recess.

6. The drive device according to claim 1, wherein both the motor housing unit and the inverter housing unit are part of a single member.
